(19) United States
(12) Patent Application Publication
(10) Pub. No.: US 2023/0136268 A1
(43) Pub. Date: May 4, 2023

(54) AUTONOMOUS BACKSIDE DATA BUFFER TO MEMORY CHIP WRITE TRAINING CONTROL

(71) Applicant: Intel Corporation, Santa Clara, CA (US)

(72) Inventors: Saravanan SETHURAMAN, Portland, OR (US); Tonia M. ROSE, Wendell, NC (US); John V. LOVELACE, Driftwood, TX (US); George VERGIS, Portland, OR (US)

(21) Appl. No.: 18/086,634

(22) Filed: Dec. 21, 2022

(51) Int. Cl. G06F 3/06

(52) U.S. Cl. CPC G06F 3/061; G06F 3/0656; G06F 3/0659; G06F 3/0673

(57) ABSTRACT

An apparatus is described. The apparatus includes data buffer to memory chip write training circuitry. The data buffer to memory chip write training circuitry to send MDQ/MDQS phase relationship programming information, write commands and read commands to the data buffer chips for multiple write training iterations without a host memory controller having provided the MDQ/MDQS phase relationship programming information, the write commands and the read commands to the data buffer to memory chip write training circuitry.

### BACKGROUND OF THE INVENTION

As the bring-up of memory systems becomes increasingly complex and time-consuming, engineers are seeking ways to reduce the complexity and/or bring-up time from the perspective of the host system.

### BRIEF DESCRIPTION OF DRAWINGS

FIGS. 1a, 1b and 1c depict a prior art DIMM and data buffer to memory chip write training process;

FIGS. 2 and 3 pertain to an improved DIMM and data buffer to memory chip write training process;

FIG. 4 depicts a computer system.

### DETAILED DESCRIPTION

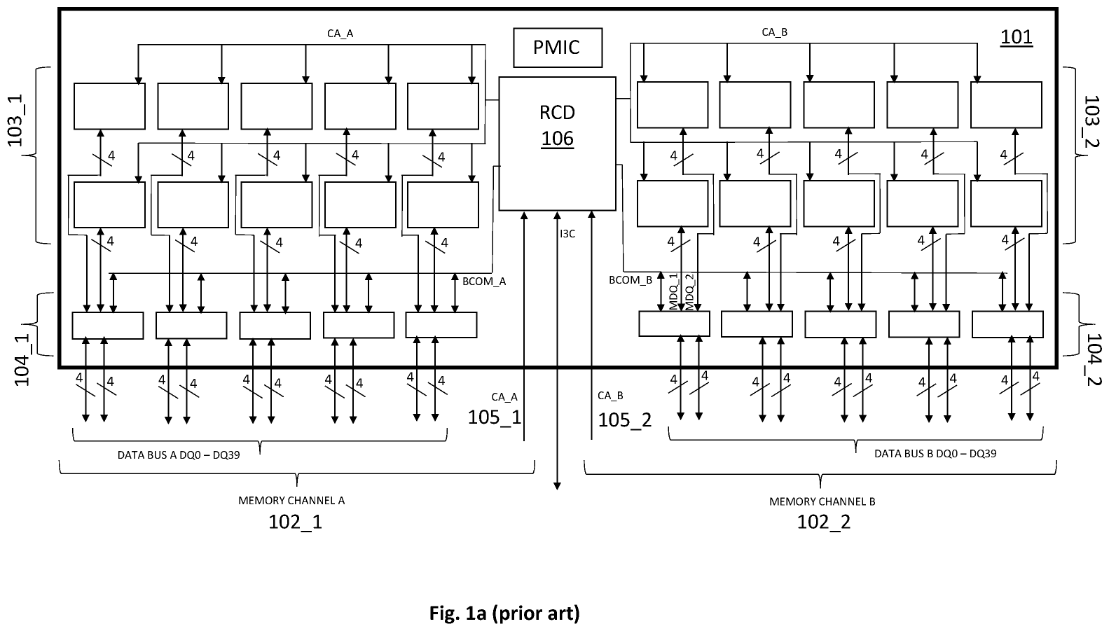

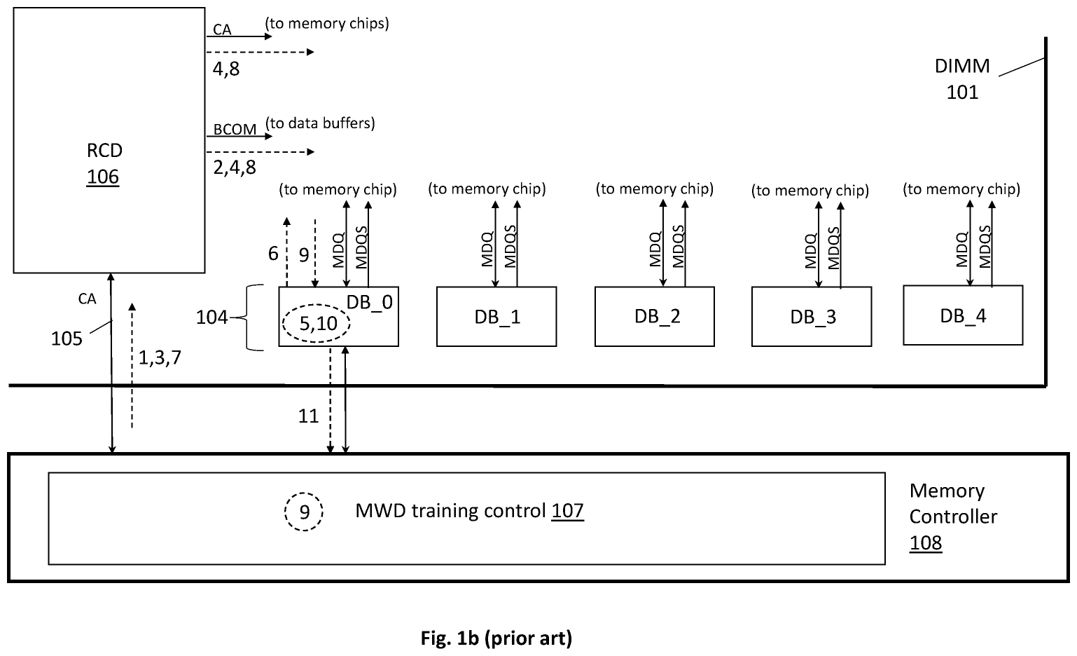

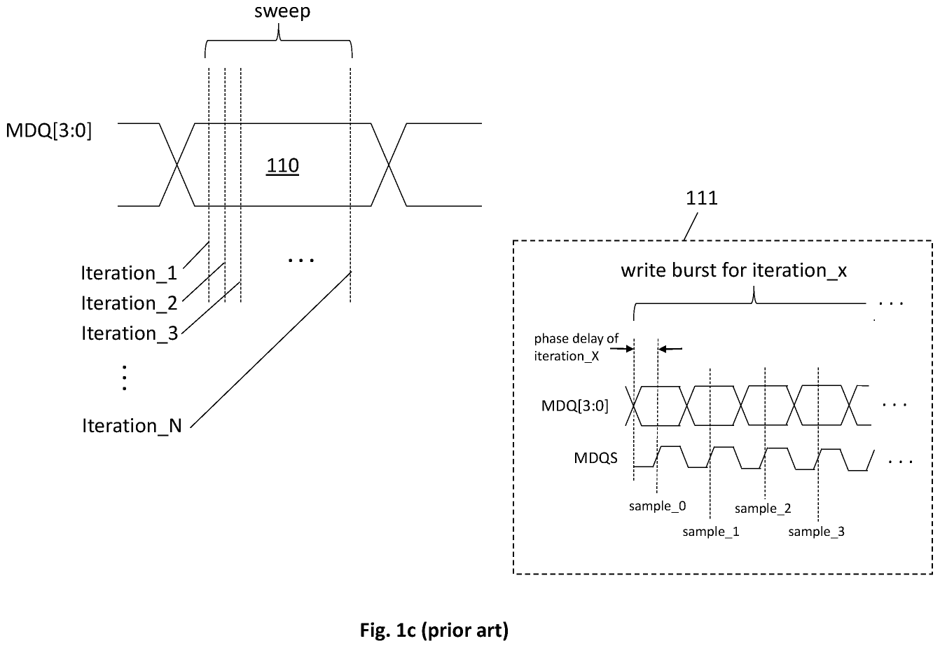

FIG. 1a shows a traditional “buffered” dual in-line memory module (DIMM) 101 that is, e.g., compliant with a Joint Electron Device Engineering Council (JEDEC) dual data rate (DDR) industry standard (e.g., DDR5). As observed in FIG. 1, a first memory channel 102_1 is coupled to the left hand (“A”) side of the DIMM 101 and a second memory channel 102_2 is coupled to the right hand (“B”) side of the DIMM 101.

A rank of memory chips 103_1 and corresponding data buffers 104_1 for the first memory channel 101_1 are disposed on the A side of the DIMM 101 while another rank of memory chips 103_2 and corresponding data buffers 104_2 for the second memory channel 101_2 are disposed on the B side of the DIMM 101.

The width of the data bus for both memory channels is 40 bits where 32 bits are for customer data and 8 bits are for error correction code (ECC) information. The 40 bit width requires ten X4 memory chips 103_1, 103_2 for each memory channel 101. The ten X4 memory chips 104_1, 104_2 are arranged per channel as a first upper group of five X4 memory chips and a second lower group of five X4 memory chips.

Each memory channel 101_1, 101_2 also includes its own respective command/address (CA) bus 105_1, 105_2. The respective CA bus 105_1, 105_2 for both memory channels 101_1, 101_2 is intercepted by the DIMM's register clock driver (RCD) chip 106 (by contrast, a memory channel's data bus wires are coupled to the corresponding data buffers 104_1, 104_2 on the DIMM 101 which are then coupled to the memory channel's rank of memory chips 103_1, 103_2).

The RCD 106 receives the command and/or address (CA) signals from the CA busses 105_1, 105_2 for both memory channels (which are generated by a host (memory controller)) and, redrives each channel's corresponding CA signals to the channel's respective memory chips 103_1, 103_2. That is, the CA signals 105_1 received for the A memory channel 101_1 are re-driven to the memory chips 103_1 and on the A side of the DIMM 101, whereas the CA signals 105_2 received for the B memory channel 101_2 are re-driven to the memory chips 103_2 on the B side of the DIMM 101.

According to various JEDEC standards, a buffer communication (BCOM) bus exists between the RCD 106 and the data buffers 104_1, 104_2 for a particular memory channel. That is, there is one BCOM bus (“BCOM_A”) that couples the RCD 106 to the data buffers 104_1 of the A memory channel and another BCOM bus (“BCOM_B”) that couples the RCD 106 to the data buffers 104_2 of the B memory channel.

Referring to FIGS. 1b and 1c, during bring-up of the DIMM 100, the data paths between the data buffers and the memory chips are trained. Here, write data emitted by a data buffer is sent over an MDQ data channel to a memory chip that is coupled to the data buffer by way of the MDQ data channel. A common implementation, as observed in FIG. 1a, is to couple two different memory chips with two different, respective MDQ data channels to a same data buffer. For ease of explanation and drawing, FIG. 1b only depicts one MDQ data channel per data buffer, and the remainder of the discussion will mostly refer to the training of a single MDQ data channel that is coupled between a single memory chip and a data buffer.

The data buffer 104 also sends an MDQS strobe signal along with the write data for a particular MDQ data channel. The memory chip is designed to latch the write data from the MDQ channel on an (e.g., rising) edge of the MDQS strobe signal.

The high frequency signal components of the MDQ data signals and/or the MDQS strobe signal complicate the write signaling from the data buffer to the memory chip. Specifically, there is apt to be an optimum phase difference between the edge of the MDQ data signals and the edge of the MDQS strobe signal where errors in the write data as received by the memory chip occur at a lower rate than all other phase differences.

The aforementioned training includes discovering the optimum phase difference and then programming the data buffer 104 to impose the optimum phase difference between its MDQ write data and its MDQS strobe for a particular MDQ data channel. By so doing, errors in the write data as received by the memory chip should be at a minimum.

As observed in FIG. 1c, the training is performed in iterations where each iteration corresponds to a specific phase relationship between the MDQ data signals and the MDQS strobe signal. During each iteration, a series of writes are performed from the buffer chip to its corresponding memory chip. Here, writes are typically performed in “bursts” of eight (DDR4) or sixteen (DDR5) cycles where the initial cycle is written to a base address that is sent from the host memory controller 108 to the memory chip by way of the appropriate CA bus. The host then increments the write address with each next cycle of the burst until the total number of cycles for the burst is reached.

Referring back to FIG. 1b, training control circuitry 107 within the host memory controller 108 sends a command 1 to a DIMM's RCD 106 for the data buffers 104 of a particular memory channel to enter the MWD training mode. The command is then forwarded 2 to the data buffers 104 from the RCD 106 via the BCOM bus. Additional commands 1, 2 from the host training circuitry 107 to the data buffers 104 through the RCD 106 can specify phase relationship configuration information for the training sequence (e.g., absolute phase values, phase increments per iteration, etc.) and write data pattern configuration information (described in more detail further below).

The first iteration then commences with the host training circuitry 107 sending a write command 3 to the RCD 106 which the RCD 106 forwards 4 to the memory chips via the memory channel's CA bus and to the data buffers 104 via the BCOM bus. Because the data path between the host memory controller 108 and the data buffers 104 has not yet been trained, data transfer integrity between the host 108 and data buffers 104 has not yet been established. As such, the data buffers 104 include write data pattern generators that internally generate 5 the training write data to be sent from the memory chips.

In particular, the data buffers 104 include LFSR circuits that generates pseudo-random bit sequences from one or more seed values that can be programmed into the LFSR circuits by the host training circuitry 107 through the RCD 106 and BCOM bus. As the data buffers 104 internally generate 5 the write training data in response to the write command 4 received from the RCD 106 via the BCOM bus, they write 6 the data to the memory chips (e.g., in a burst sequence).

The host then sends a read command 7 to the RCD 106. The RCD 106 forwards 8 the read command to the memory chips via the CA bus and the data buffers via the BCOM bus. In response to the read command, the data buffers 104 read the just written training data from the memory chips 9. Because the integrity of the data channel between the data buffers 104 and the host memory controller 108 has not yet been verified, the data buffers 104 also include internal comparison circuitry that compares 10 the read data against the generated write data pattern. Any errors are reported by the data buffers 104 to the host training circuitry 107 (by way of toggling logic values at low speed on the data channel between the data buffers and the host memory controller 108 so that the host memory controller 108 can reliably sense them).

The process can then be repeated, e.g., to implement a next iteration of the training sequence.

Additionally, the training can include determining an appropriate reference level VREF for the respective memory chip that is coupled to each MDQ channel. Here, VREF is the voltage level that a memory chip uses to determine whether a logic 1 or logic 0 exists on each respective wire of an MDQ data channel when the memory chip latches data on the appropriate edge of the corresponding MDQS strobe.

According to one training approach, each iteration corresponds to a particular MDQ and MDQS phase relationship, where a “sweep” of different VREF voltages is performed. Then, a next iteration is performed with a next (different) MDQ and MDQS phase relationship, where the same “sweep” of different VREF voltages is performed.

After all MDQ and MDQ phase relationships have been swept through, the host training circuitry 107 determines the optimum MDQ/MDQS phase relationship and VREF for each MDQ channel across the MDQ channels.

A problem is that the involvement of the host 107, 108 complicates the training process.

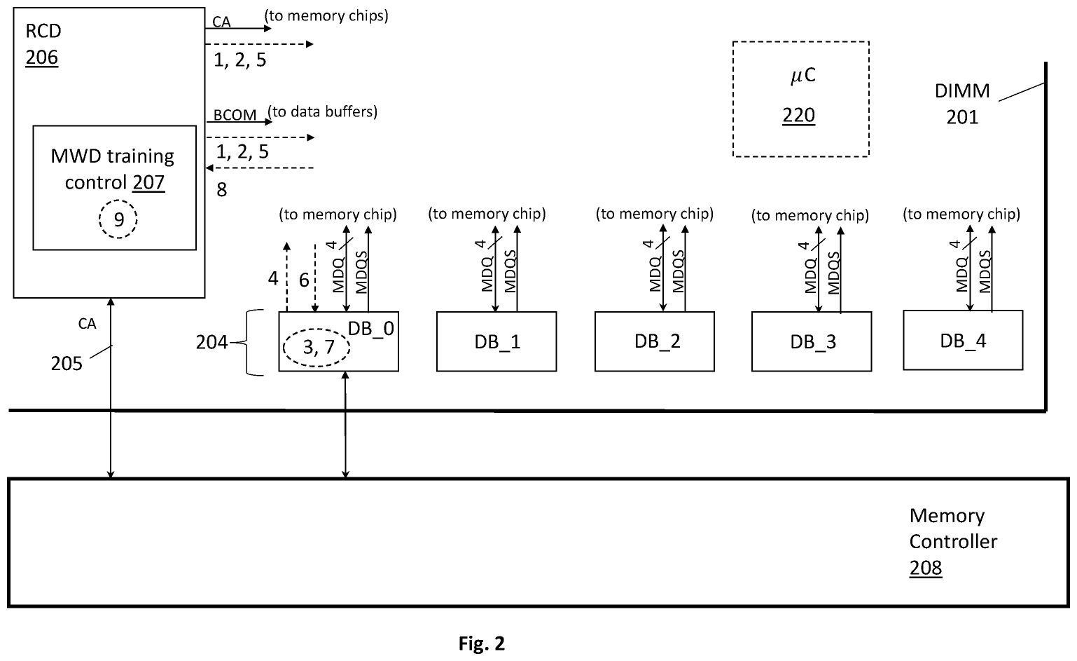

An improvement, referring to FIG. 2, is to integrate the MWD training control circuitry 207 into the RCD 206. With the MWD training control circuitry 207 integrated into the RCD 206 the training can be controlled on the DIMM 200 with minimal host involvement.

According to one approach, the RCD 206 can be initially commanded by the host memory controller 208 to start the write training sequence, or, the RCD 206 can initiate the write training sequence on its own accord, e.g., based on the state of the DIMM's bring-up (e.g., the training of the read channel from the memory chips to the data buffers has just been successfully completed).

Once the write training sequence has started, as observed to FIG. 2, the RCD 206 sends a command 1 over the BCOM bus to cause the data buffers 204 to enter the MWD write training mode. Additional initial commands 1 can program MDQ/MDQS phase delay configuration information (e.g., absolute phase values, phase sweep increments, etc.), seed values for the data buffers' internal write data generation circuits into the data buffers. The RCD can also initially program VREF values (voltage sweep increments) into the memory chips.

After the data buffers 204 are entered into the write training mode and configured, the RCD's 206 training control circuitry 207 starts the first iteration of the write training sequence by sending a write command 2 to the memory chips over the CA bus and to the data buffers 204 over the BCOM bus. Here, the RCD's write training control circuitry 207 includes logic circuitry to generate 2 a write command without having earlier received a corresponding write command from the host (nominally the RCD forwards write commands from the host to the data buffers).

In response to the write command, the data buffers 204 internally generate 3 the write training data and the write 4 the data, e.g., as a write burst, into the memory chips. After the write, the RCD's 206 training control circuitry 207 sends a read command 5 to the data buffers 204 over the CA bus of the corresponding memory channel. Here, the RCD's write training control circuitry 207 includes logic circuitry to generate 5 a read command without having earlier received a corresponding read command from the host (nominally the RCD forwards read commands from the host to the data buffers). The read command 5 is sent to the memory chips over the CA bus and to the data buffers 204 over the BCOM bus.

In response to the read command 5, the data buffers 204 read 6 the just written data, e.g., as a read data burst, and internally compare 7 the read data against the internally generated write data patterns (according to one embodiment, the data buffers include two instances of write pattern generation circuitry where one instance is used for writes and the other instance is used for reads (where both instances generate the same pattern)). Any errors are then reported to the RCD 8 via the BCOM bus. In an alternate approach the errors are reported to the RCD through an I3C bus that also couples the RCD 206 to the data buffers 204. I3C is an industry standard bus specified by MIPI.

The iteration can then continue with the same MDQ/MDQS phase setting but sweeps the memory chips' VREF values.

The RCD 206 then analyzes the data, and can begin a next iteration by repeating the process described just above, e.g., with new phase MDQ/MDQS phase configurations and/or new write data patterns.

In various embodiments, rather than implement the write training control entirely in the RCD 206, write training control is implemented entirely or partially in a micro-controller 220 that is on the DIMM but not within the RCD 206 (e.g., as a stand alone micro-controller or an embedded micro-controller in some other chip on the DIMM such as the serial presence detect (SPD) chip). In this case, as just one example, the micro-controller receives testing results 8 from the data buffers and determines appropriate data buffer configurations 1 and control flow across iterations 9, Notably, as part of the control flow, the micro-controller 220 can send the RCD 206 respective commands to issue the write and read commands 2, 5 when appropriate. In other embodiments, the micro-controller 220 and some other chip on the DIMM (e.g., RCD, SPD) share in the functions/roles of the write training control and therefore together form the write training circuitry.

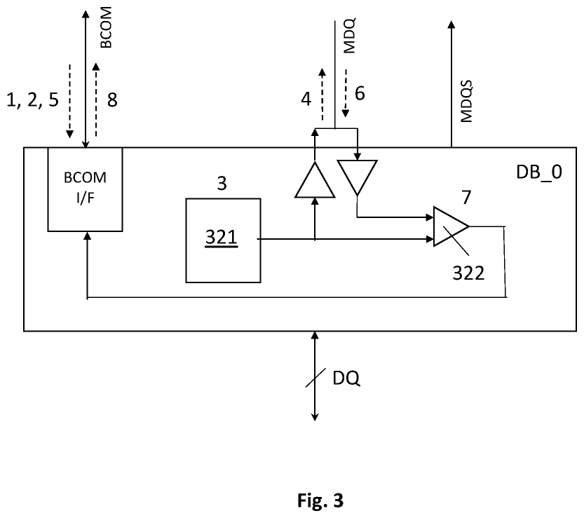

FIG. 3 shows a data buffer chip DB_0 that can be used to implement the improved write data training process. As observed in FIG. 3, after the data buffer has been programmed 1 and receives a write command 2, the write data pattern generator 321 generates 3 a write data pattern that is written 4 to the memory chip(s). Then, after the data buffer receives a read command 5, the just written data is read back 6 and compared 7 against the write data pattern (a second instance of the generator 321 can be integrated into the data buffer to generate the pattern that the read data is compared against).

Unlike the traditional approach, however, where mis-compare errors are reported to the host via the data bus (DQ) of the memory channel that exists between the host and data buffer chip, instead mis-compare errors are reported 8 to the RCD via the BCOM bus or through an I3C bust (not shown). Note that the RCD's control circuitry 207 can poll the data buffers for their test results (mis-compare error results) at the end of an iteration. In response, the data buffers provide the results through the BCOM bus or I3C bus.

In various embodiments the MDQ/MDQS phase relationship is specified as a temporal offset of the MDQ signals with respect to the MDQS rising edge.

According to one DDR6 implementation, there are 32 transfers per burst and the RCD's control circuitry 206 is designed to issue eight write burst commands (with corresponding read commands) per iteration. Here, the data buffer includes two data test pattern generators, LFSR0 and LFSR1. LFSR0 provides odd bits of a test data pattern and LFSR1 provides even bits of the test data pattern. In various embodiments LFSR0 and LFSR1 generate extended (16 bit) repeating patterns.

In various embodiments the RCD 206 and data buffers are implemented with dedicated hardwired circuitry, programmable circuitry (e.g., field programmable gate array (FPGA), circuitry that executes some form of program code such as the SSD's firmware (e.g., controller, processor) or any combination of these.

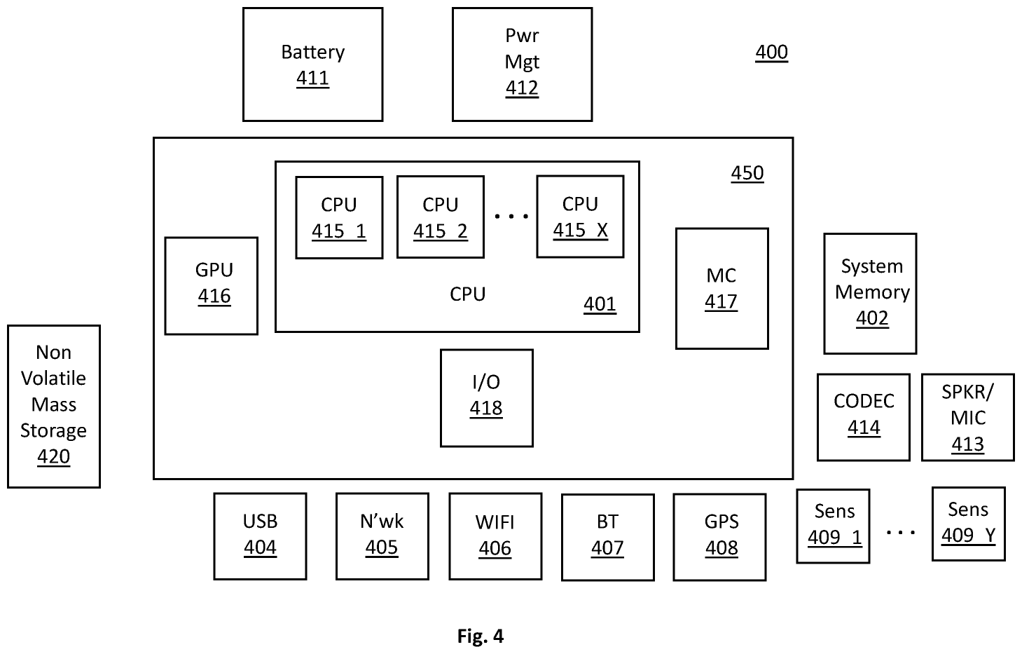

FIG. 4 depicts a basic computing system. The basic computing system 400 can include a central processing unit (CPU) 401 (which may include, e.g., a plurality of general purpose processing cores 415_1 through 415_X) and a main memory controller 417 disposed on a multi-core processor or applications processor, main memory 402 (also referred to as “system memory”), a display 403 (e.g., touchscreen, flat-panel), a local wired point-to-point link (e.g., universal serial bus (USB)) interface 404, a peripheral control hub (PCH) 418; various network I/O functions 405 (such as an Ethernet interface and/or cellular modem subsystem), a wireless local area network (e.g., WiFi) interface 406, a wireless point-to-point link (e.g., Bluetooth) interface 407 and a Global Positioning System interface 408, various sensors 409_1 through 409_Y, one or more cameras 410, a battery 411, a power management control unit 412, a speaker and microphone 413 and an audio coder/decoder 414.

An applications processor or multi-core processor 450 may include one or more general purpose processing cores 415 within its CPU 401, one or more graphical processing units 416, a main memory controller 417 and a peripheral control hub (PCH) 418 (also referred to as I/O controller and the like). The general purpose processing cores 415 typically execute the operating system and application software of the computing system. The graphics processing unit 416 typically executes graphics intensive functions to, e.g., generate graphics information that is presented on the display 403. The main memory controller 417 interfaces with the main memory 402 to write/read data to/from main memory 402. The main memory 402 can include one or more DIMMs having an RCD that controls data buffer to memory chip write training as discussed at length above. The power management control unit 412 generally controls the power consumption of the system 400. The peripheral control hub 418 manages communications between the computer's processors and memory and the I/O (peripheral) devices.

Other high performance functions such as computational accelerators, machine learning cores, inference engine cores, image processing cores, infrastructure processing unit (IPU) core, etc. can also be integrated into the computing system.

Each of the touchscreen display 403, the communication interfaces 404-407, the GPS interface 408, the sensors 409, the camera(s) 410, and the speaker/microphone codec 413, 414 all can be viewed as various forms of I/O (input and/or output) relative to the overall computing system including, where appropriate, an integrated peripheral device as well (e.g., the one or more cameras 410). Depending on implementation, various ones of these I/O components may be integrated on the applications processor/multi-core processor 450 or may be located off the die or outside the package of the applications processor/multi-core processor 450. The computing system also includes non-volatile mass storage 420 which may be the mass storage component of the system which may be composed of one or more non-volatile mass storage devices (e.g., hard disk drive, solid state drive, etc.). The non-volatile mass storage 420 may be implemented with any of solid state drives (SSDs), hard disk drive (HDDs), etc.

Embodiments of the invention may include various processes as set forth above. The processes may be embodied in program code (e.g., machine-executable instructions). The program code, when processed, causes a general-purpose or special-purpose processor to perform the program code's processes. Alternatively, these processes may be performed by specific/custom hardware components that contain hard wired interconnected logic circuitry (e.g., application specific integrated circuit (ASIC) logic circuitry) or programmable logic circuitry (e.g., field programmable gate array (FPGA) logic circuitry, programmable logic device (PLD) logic circuitry) for performing the processes, or by any combination of program code and logic circuitry.

Elements of the present invention may also be provided as a machine-readable medium for storing the program code. The machine-readable medium can include, but is not limited to, floppy diskettes, optical disks, CD-ROMs, and magneto-optical disks, FLASH memory, ROMs, RAMs, EPROMs, EEPROMs, magnetic or optical cards or other type of media/machine-readable medium suitable for storing electronic instructions.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. An apparatus, comprising:
a dual in-line memory module (DIMM) comprising i); ii); and, iii) below:
i) a memory chip;
ii) a data buffer chip comprising write data pattern generation circuitry and comparison circuitry, the data buffer chip to write data generated by the data pattern generation circuitry into the memory chip during training of a write data path that exists between the data buffer chip and the memory chip, the data buffer chip to read the written data during the training, the comparison circuitry to compare the read data for errors during the training;
iii) training circuitry for the write data path, the training circuitry to, during the training, determine when a write command is to be sent to the data buffer chip to perform the write, determine when a read command is to be sent to the data buffer chip to perform the read, and receive from the data buffer chip mis-comparison information resulting from the compare.

2. The apparatus of claim 1 further comprising a bus coupled between the data buffer chip and the training circuitry, the mis-comparison information sent by the data buffer to the training circuity over the bus.

3. The apparatus of claim 2 wherein the bus is a BCOM bus.

4. The apparatus of claim 2 wherein the bus is an I3C bus.

5. The apparatus of claim 1 wherein the data buffer chip is to transmit the write data with a strobe signal having a pre-programmed phase relationship with the write data per training iteration.

6. The apparatus of claim 3 wherein the phase relationship is determined by the training circuitry and programmed into the data buffer chip from the training circuitry.

7. The apparatus of claim 1 wherein the training circuitry is to control multiple iterations of the training, wherein, different iterations are characterized by different phase relationships between write data written into the memory chip by the data buffer and a strobe signal sent to the memory chip by the data buffer chip.

8. The apparatus of claim 1 wherein the training circuitry is to determine the phase relationships.

9. The apparatus of claim 1 wherein the training circuitry is to determine reference voltages.

10. An apparatus, comprising:
data buffer to memory chip write training circuitry to be disposed on a DIMM, the data buffer to memory chip write training circuitry to send MDQ/MDQS phase relationship programming information, write commands and read commands to the data buffer chips for multiple write training iterations without a host memory controller having provided the MDQ/MDQS phase relationship programming information, the write commands and the read commands to the data buffer to memory chip write training circuitry.

11. The apparatus of claim 10 wherein the data buffer to memory chip write training circuitry is to cause the data buffers to be polled for write/read comparison results.

12. The apparatus of claim 11 wherein the write training circuitry is to receive the write/read comparison results upon an I3C bus.

13. The apparatus of claim 10 wherein the data buffer to memory chip write training circuitry is to determine an appropriate VREFs for the memory chips to receive write data from the data buffers.

14. A computing system, comprising:
a plurality of processing cores;
a memory controller coupled to the processing cores;
a main memory coupled to the memory controller, the main memory comprising a DIMM, the DIMM comprising i); ii); and, iii) below:
i) a memory chip;
ii) a data buffer chip comprising write data pattern generation circuitry and comparison circuitry, the data buffer chip to write data generated by the data pattern generation circuitry into the memory chip during training of a write data path that exists between the data buffer chip and the memory chip, the data buffer chip to read the written data during the training, the comparison circuitry to compare the read data for errors during the training;
iii) training circuitry for the write data path, the training circuitry to, during the training, generate a write command and send the write command to the data buffer chip to perform the write, generate a read command and send the read command to the data buffer chip to perform the read, and receive from the data buffer chip mis-comparison information resulting from the compare.

15. The computing system of claim 14 further comprising a bus coupled between the data buffer chip and the training circuitry, the mis-comparison information sent by the data buffer to the training circuitry chip over the bus.

16. The computing system of claim 14 wherein the data buffer chip is to transmit the write data with a strobe signal having a pre-programmed phase relationship with the write data per training iteration.

17. The computing system of claim 16 wherein the phase relationship is determined by the training circuitry and programmed into the data buffer chip by the training circuitry.

18. The computing system of claim 14 wherein the training circuitry is to control multiple iterations of the training, wherein, different iterations are characterized by different phase relationships between write data written into the memory chip by the data buffer and a strobe signal sent to the memory chip by the data buffer chip.

19. The computing system of claim 14 wherein the training circuitry is to determine the phase relationships.

20. The computing system of claim 1 wherein the training circuitry is to determine reference voltages.
